(19) United States
(12) Patent Application Publication
(10) Pub. No.: US 2019/0081235 A1
(43) Pub. Date: Mar. 14, 2019

(54) SEMICONDUCTOR MEMORY DEVICE

(71) Applicant: TOSHIBA MEMORY CORPORATION, Tokyo (JP)

(72) Inventor: Eiji KITAGAWA, Yokkaichi Mie (JP)

(21) Appl. No.: 15/907,907

(22) Filed: Feb. 28, 2018

(30) Foreign Application Priority Data
Sep. 13, 2017 (JP) 2017-175890

(51) Int. Cl. H01L 43/08; H01L 43/10; H01L 27/22; G11C 11/16

(52) U.S. Cl. CPC H01L 43/08; H01L 43/10; H01L 43/12; G11C 11/161; H01L 27/228

(57) ABSTRACT

According to one embodiment, a semiconductor memory device includes a variable resistance element comprising a first ferromagnetic layer, a second ferromagnetic layer, and a non-magnetic layer between the first ferromagnetic layer and the second ferromagnetic layer. The non-magnetic layer includes a para-electric layer on an upper surface of the first ferromagnetic layer, and a ferro-electric layer on an upper surface of the para-electric layer and on a lower surface of the second ferromagnetic layer.

### CROSS-REFERENCE TO RELATED APPLICATION

This application is based upon and claims the benefit of priority from Japanese Patent Application No. 2017-175890, filed Sep. 13, 2017, the entire contents of which are incorporated herein by reference.

### FIELD

Embodiments described herein relate generally to a semiconductor memory device.

### BACKGROUND

A semiconductor memory device including a variable resistance element is known.

### DESCRIPTION OF THE DRAWINGS

FIG. 1 is a block diagram showing a configuration of a semiconductor memory device according to a first embodiment;

FIG. 2 is a cross-sectional view showing a configuration of a memory cell of the semiconductor memory device according to the first embodiment;

FIG. 3 is a cross-sectional view showing a configuration of a variable resistance element of the semiconductor memory device according to the first embodiment;

FIG. 4 is a table outlining a difference in crystal structure due to a combination of elements constituting a ferro-electric layer of the semiconductor memory device according to the first embodiment;

FIG. 5 is a table for showing the difference in parasitic resistance due to the combination of elements constituting the ferro-electric layer of the semiconductor memory device according to the first embodiment;

FIG. 6 is a timing chart providing an overview of a write operation of the semiconductor memory device according to the first embodiment;

FIG. 7 is a schematic diagram illustrating an example of resistance variation of a variable resistance element in an operation of writing data of “0”;

FIG. 8 is a schematic diagram illustrating an example of resistance variation of a variable resistance element in an operation of writing data of “1”;

FIG. 9 is a flowchart of a method of manufacturing the variable resistance element of the semiconductor memory device according to the first embodiment;

FIG. 10 is a flowchart of a method of manufacturing the variable resistance element of the semiconductor memory device according to the first embodiment; and

FIG. 11 is a flowchart setting forth steps in a method of manufacturing the variable resistance element of the semiconductor memory device according to the first embodiment.

### DETAILED DESCRIPTION

Embodiments provide a semiconductor memory device capable of improving a resistance ratio of a variable resistance element.

In general, according to one embodiment, a semiconductor memory device includes a variable resistance element comprising a first ferromagnetic layer, a second ferromagnetic layer, and a non-magnetic layer between the first ferromagnetic layer and the second ferromagnetic layer. The non-magnetic layer includes a para-electric layer on an upper surface of the first ferromagnetic layer, and a ferro-electric layer on an upper surface of the para-electric layer and on a lower surface of the second ferromagnetic layer.

Hereinafter, embodiments will be described with reference to the drawings. In the following description, constituent elements having the same functions and configurations are given the same reference signs in the figures. In addition, when distinguishing a plurality of constituent elements having common reference signs, the common reference signs are appended with suffixes. In the case where a distinction is not particularly required for a plurality of constituent elements, only the common reference signs are attached to the plurality of constituent elements, and the suffixes are not appended.

### 1. First Embodiment

A semiconductor memory device according to a first embodiment will be described. The semiconductor memory device according to the first embodiment is a memory device that uses, as a memory element, a variable resistance element using a tunnel magneto-resistance effect (TMR effect) due to a magnetic tunnel junction (MTJ) and a tunnel electro-resistance effect (TER effect) due to a ferroelectric tunnel junction (FTJ). In addition, the semiconductor memory device according to the first embodiment includes a magnetoresistive random access memory (MRAM) based on perpendicular magnetization.

### 1.1 Configuration

First, a configuration of the semiconductor memory device according to the first embodiment will be described.

1.1.1 Configuration of Semiconductor Memory Device

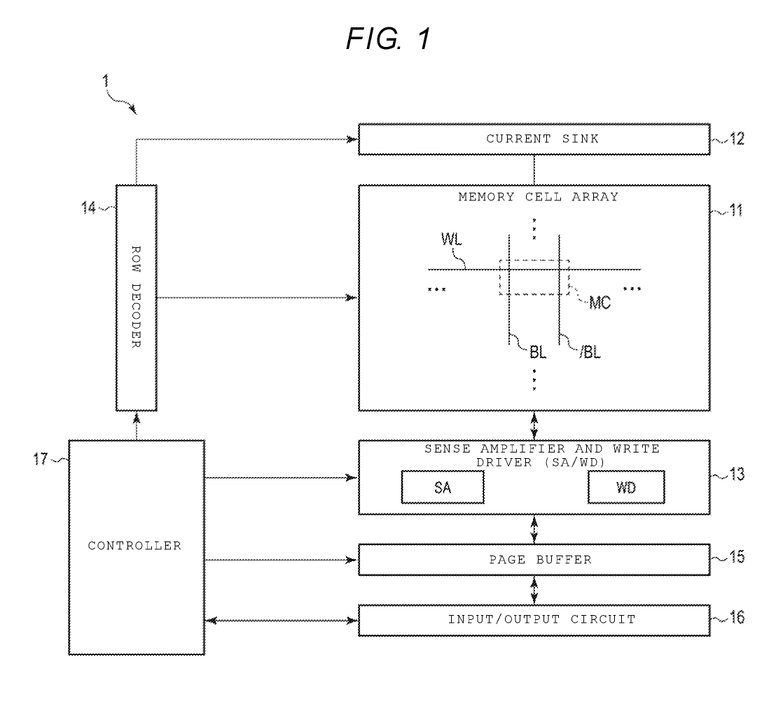

FIG. 1 is a block diagram illustrating a configuration of a semiconductor memory device according to the first embodiment. As illustrated in FIG. 1, a semiconductor memory device 1 includes a memory cell array 11, a current sink 12, a sense amplifier and write driver (SA/WD) 13, a row decoder 14, a page buffer 15, an input/output circuit 16, and a controller 17.

The memory cell array 11 includes a plurality of memory cells MC arranged in rows and columns. For example, memory cells MC in the same row are connected to the same word line WL, and both ends of the string of memory cells MC in the same column are connected to the same bit line BL and the same source line /BL.

The current sink 12 is connected to the bit line BL and the source line /BL. The current sink 12 sets the bit line BL or the source line /BL to a ground potential in write and read operations of data.

The SA/WD 13 is connected to the bit line BL and the source line /BL. The SA/WD 13 supplies a current to the memory cell MC to be operated via the bit line BL and the source line /BL, and writes data to the memory cell MC. In addition, the SA/WD 13 supplies current to the memory cell MC to be operated via the bit line BL and the source line /BL, and reads data from the memory cell MC. More specifically, the write driver of the SA/WD 13 writes data to the memory cell MC, and the sense amplifier of the SA/WD 13 reads data from the memory cell MC.

The row decoder 14 is connected to the memory cell array 11 via the word line WL. The row decoder 14 decodes a row address for designating a row of the memory cell array 11. Then, a word line WL is selected according to the decoding result, and a voltage necessary for the operations of writing and reading data is applied to the selected word line WL.

The page buffer 15 temporarily stores data to be written into the memory cell array 11 and data read from the memory cell array 11 in data units called pages.

The input/output circuit 16 transmits various signals received from outside of the semiconductor memory device 1 to the controller 17 and the page buffer 15, and transmits various types of information from the controller 17 and the page buffer 15 to the outside of the semiconductor memory device 1.

The controller 17 is connected to the current sink 12, the SA/WD 13, the row decoder 14, the page buffer 15, and the input/output circuit 16. The controller 17 controls the current sink 12, the SA/WD 13, the row decoder 14, and the page buffer 15 according to various signals received from the outside of the semiconductor memory device 1 by the input/output circuit 16.

1.1.2 Configuration of Memory Cell

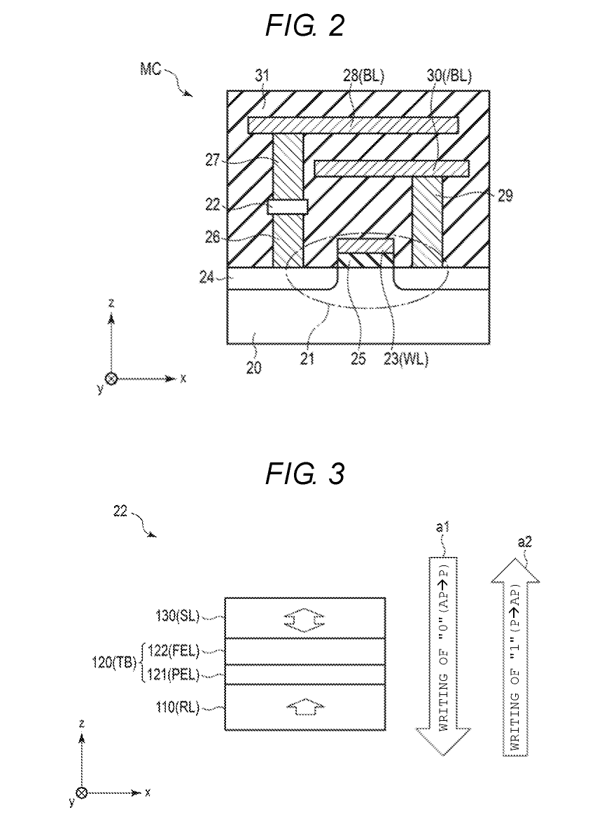

A configuration of the memory cell of the semiconductor memory device according to the first embodiment will be described with reference to FIG. 2. In the following description, a plane parallel to the semiconductor substrate 20 is defined as an x-y plane, an axis perpendicular to the x-y plane is defined as a z-axis. An X-axis and a y-axis are defined as axes orthogonal to each other in the x-y plane. FIG. 2 illustrates an example of a cross-sectional view of the memory cell MC of the semiconductor memory device 1 according to the first embodiment in an x-z plane.

As illustrated in FIG. 2, the memory cell MC is provided on the semiconductor substrate 20, and includes a select transistor 21 and a variable resistance element 22. The select transistor 21 is provided as a switch for controlling supplying and stopping of current at the time of writing and reading data to and from the variable resistance element 22. The variable resistance element 22 includes a plurality of stacked films, and can switch a resistance value between a low resistance state and a high resistance state when a current flows in a direction perpendicular to the film surface. The variable resistance element 22 is capable of writing data according to a change in the resistance state thereof, and functions as a memory element which stores the written data in a nonvolatile manner, and is capable of being read to read the data.

The select transistor 21 includes a gate connected to an interconnect layer 23 functioning as the word line WL, a pair of source regions and drain regions 24 provided on the surface of the semiconductor substrate 20 at opposed ends thereof in the x-direction of the gate 24. A region of the select transistor 21 included in the semiconductor substrate 20 is also referred to as an active region. For example, the active region is insulated from an active region of another memory cell MC by a shallow trench isolation (STI) (not illustrated) so as not to be electrically connected to the

The interconnect layer 23 is provided in a y-direction via an insulating layer 25 on the semiconductor substrate 20, and is connected in common to a gate of a select transistor 21 (not illustrated) of another memory cell MC arranged in the y-direction, for example. The interconnect layer 23 is arranged in the x-direction, for example.

One end of the select transistor 21 is connected to a lower surface of the variable resistance element 22 via a contact plug 26 provided on the source region or drain region 24. A contact plug 27 is provided on an upper surface of the variable resistance element 22. The variable resistance element 22 is connected to an interconnect layer 28, which functions as the bit line BL, via the contact plug 27. The interconnect layer 28 extends in the x-direction, and is connected in common to the other end of a variable resistance element 22 (not illustrated) of another memory cell MC arranged in the x-direction, for example.

The other end of the select transistor 21 is connected to an interconnect layer 30, which functions as the source line /BL, via a contact plug 29 provided on the source region or the drain region 24. The interconnect layer 30 extends in the x-direction, and is connected in common to the other end of the select transistor 21 (not illustrated) of another memory cell MC arranged in the x-direction, for example.

The interconnect layers 28 and 30 are arranged in the y-direction, for example. The interconnect layer 28 is located above the interconnect layer 30, for example. Although not illustrated in FIG. 2, the interconnect layers and 30 are located to avoid physical and electrical interference with each other. The select transistor 21, the variable resistance element 22, the interconnect layers 23, 28, and 30, and the contact plugs 26, 27, and 29 are covered with an interlayer insulating film 31.

The variable resistance element 22 (not illustrated) arranged in the x-direction or the y-direction with respect to the variable resistance element 22 is provided on the same layer, for example. That is, the variable resistance elements 22 in the memory cell array 11 are arranged in a direction in which the semiconductor substrate 20 extends, for example.

1.1.3 Configuration of the Variable Resistance Element

A configuration of the variable resistance element of the semiconductor memory device according to the first embodiment will be described with reference to FIG. 3. FIG. 3 illustrates an example of a cross-sectional view of the variable resistance element of the semiconductor memory device according to the first embodiment taken along a plane perpendicular to the x-y plane.

As illustrated in FIG. 3, the variable resistance element includes a ferromagnetic layer 110 functioning as a reference layer, a non-magnetic layer 120 functioning as a tunnel barrier layer, and a ferromagnetic layer 130 functioning as a storage layer. In the drawings subsequent to FIG. 3, the ferromagnetic layer 110, the non-magnetic layer 120, and the ferromagnetic layer 130 are also denoted as “RL”, “TB”, and “SL”, respectively.

A cap layer (not illustrated) may be further stacked on an upper surface of the ferromagnetic layer 130, and a ferromagnetic layer (not illustrated) oriented in an opposite direction to a magnetization orientation of the ferromagnetic layer 110 may be further inserted between the cap layer and the ferromagnetic layer 130. Furthermore, non-magnetic layer (not illustrated) may be inserted between an inserted ferromagnetic layer and the ferromagnetic layer 130 to cut magnetic exchange coupling. In addition, an under layer may be further stacked on a lower surface of the ferromagnetic layer 110, and a ferromagnetic layer (not illustrated) oriented in an opposite direction to the magnetization orientation of the ferromagnetic layer 110 may be further inserted between the under layer and the ferromagnetic layer 110. Furthermore, a non-magnetic layer (not illustrated) may be inserted between an inserted ferromagnetic layer and the ferromagnetic layer 110 to make up for SAF coupling. These ferromagnetic layers, which are not illustrated, function as a shift cancel layer for canceling a shift magnetic field applied to the ferromagnetic layer 130 from the ferromagnetic layer 110.

The variable resistance element 22 is configured in which a plurality of films is stacked in the z-axis direction in order of the ferromagnetic layer 110, the non-magnetic layer 120, and the ferromagnetic layer 130, in the direction from the semiconductor substrate 20. The variable resistance element 22 functions as a perpendicular magnetization-type MTJ element in which each of the ferromagnetic layers 110 and 130 have a perpendicular magnetic anisotropy to the film surface. In addition, the variable resistance element 22 also functions as an FTJ element in which its resistance state changes according to the magnitude of an electric field in a direction perpendicular to the film surface.

The ferromagnetic layer 110 is a ferromagnetic layer having an orientation of an easy axis of magnetization in the direction perpendicular to the film surface, and contains, for example, cobalt-iron-boron (CoFeB) or iron boride (FeB). In addition, the ferromagnetic layer 110 may contain cobalt-platinum (CoPt), cobalt-nickel (CoNi), or cobalt palladium (CoPd). The magnetization orientation of the ferromagnetic layer 110 is fixed and is oriented toward either the semiconductor substrate 20 or the ferromagnetic layer 130 (being oriented toward the ferromagnetic layer 130 in the example of FIG. 3). It should be noted that the “magnetization orientation is fixed” means that the magnetization orientation does not change due to a current having a magnitude capable of reversing the magnetization orientation of the ferromagnetic layer 130.

The non-magnetic layer 120 functions as a tunnel barrier layer for generating a tunnel magneto-resistance effect of changing a resistance value according to the magnetization direction of ferromagnetic layer 130.

The non-magnetic layer 120 includes a plurality of non-magnetic films having dielectric properties. Specifically, for example, the non-magnetic layer 120 includes a para-electric layer 121 and a ferro-electric layer 122. In the drawings subsequent to FIG. 3, the para-electric layer 121 and the ferro-electric layer 122 are also denoted as “PEL” and “FEL”, respectively.

The para-electric layer 121 contains, for example, magnesium oxide (MgO) having a crystal structure of a cubic crystal system. The para-electric layer 121 functions as a seed layer for generating a heteroepitaxial growth of the ferro-electric layer 122 in a crystallization process of the adjacent ferro-electric layer 122. That is, the para-electric layer 121 promotes crystallization of a similar crystal structure at an interface with the adjacent layer to be formed thereon.

The ferro-electric layer 122 functions as a layer for generating a tunnel electro-resistance effect of changing a resistance value according to the magnitude of the applied electrical field and the magnetization direction of ferromagnetic layer 130. In addition, the ferro-electric layer 122 has a structure capable of generating the tunnel electro-resistance effect without impairing the function as the tunnel magneto-resistance effect of the non-magnetic layer 120. Specifically, when the ferro-electric layer 122 has a perovskite structure, both of the tunnel magneto-resistance effect and the tunnel electro-resistance effect can be achieved. The ferro-electric layer having the perovskite structure capable of achieving both of the tunnel magneto-resistance effect and the tunnel electro-resistance effect is disclosed in scientific literature, for example, “Leina Jiang, et. al, “Enhanced tunneling electroresistance in multiferroic tunnel junctions due to the reversible modulation of orbitals overlap”, Applied Physics Letters 109, 192902, 2016”. The entire contents of the scientific literature are incorporated herein by reference.

In the case of where the ferro-electric layer 122 has, for example, a perovskite structure (also referred to as an ABO₃ structure) represented by ABO₃, the ferro-electric layer 122 can contain at least one of calcium (Ca), strontium (Sr), barium (Ba), and lanthanum (La) as the element A and at least one of titanium (Ti), vanadium (V), chromium (Cr), manganese (Mn), iron (Fe), cobalt (Co), nickel (Ni), and aluminum (Al) as the element B. Here, the elements A and B are metal elements, and element O is oxygen. An example of a specific configuration of the ferro-electric layer 122 will be described below.

It is noted that the ferro-electric layer 122 is converted into a crystalline perovskite structure from an amorphous state by being kept in a high-temperature environment such as by annealing, for example. As described above, the ferro-electric layer 122 can promote crystallization using the crystal structure of the para-electric layer 121 as a crystal nucleus.

The ferromagnetic layer 130 is a ferromagnetic layer having an orientation of an easy axis of magnetization in the direction perpendicular to the film surface, and contains, for example, cobalt-iron-boron (CoFeB) or iron boride (FeB). The ferromagnetic layer 130 has a magnetization orientation oriented toward either the ferromagnetic layer 110 or the interconnect layer 28. The magnetization orientation of the ferromagnetic layer 130 is set to be easily reversed as compared with the ferromagnetic layer 110. The ferromagnetic layer 130 is preferably in contact with the ferro-electric layer 122.

In the first embodiment, a spin injection write method can be applied in which a write current is directly passed through a variable resistance element 22 and the magnetization orientation of the ferromagnetic layer 130 is controlled by the write current. The variable resistance element 22 can take either the low resistance state or the high resistance state depending on whether the relative relation between the magnetization orientations of the ferromagnetic layers 110 and 130 is parallel or anti-parallel.

In the first embodiment, by use of the write current described above, the magnetization orientations of the ferromagnetic layers 110 and 130 are controlled and the resistance value of the ferro-electric layer 122 is also controlled. The variable resistance element 22 can make a difference between the low resistance state and the high resistance state of the variable resistance element 22 more remarkable by the change in the resistance state of the ferro-electric layer 122.

When a write current is passed through the variable resistance element 22 in a direction indicated by the arrow a1 in FIG. 3, that is, from the ferromagnetic layer 130 toward the ferromagnetic layer 110, the relative relationship between the magnetization orientations of the ferromagnetic layers 110 and 130 becomes parallel. In addition, the ferro-electric layer 122 goes into a low resistance state due to the write current. In this state, the resistance value of the variable resistance element 22 becomes lowest. Such a state is also called “P (Parallel) state”, for example, and is defined as a state of data of “0”, for example.

When a write current is passed through the variable resistance element 22 in a direction indicated by the arrow a2 in FIG. 3, that is, from the ferromagnetic layer 110 toward the ferromagnetic layer 130, the relative relationship between the magnetization orientations of the ferromagnetic layers 110 and 130 becomes anti-parallel. In addition, the ferro-electric layer 122 goes into a high resistance state due to the write current. In such a state, the resistance value of the variable resistance element 22 becomes highest. Such a state is also called “AP (Anti-Parallel) state”, for example, and is defined as a state of data of “1”, for example.

1.1.4 Configuration of Ferro-Electric Layer

A configuration of the ferro-electric layer in the variable resistance element of the semiconductor memory device according to the first embodiment will be described below.

1.1.4.1 Crystal Structure

First, a crystal structure used for the ferro-electric layer 122 will be described.

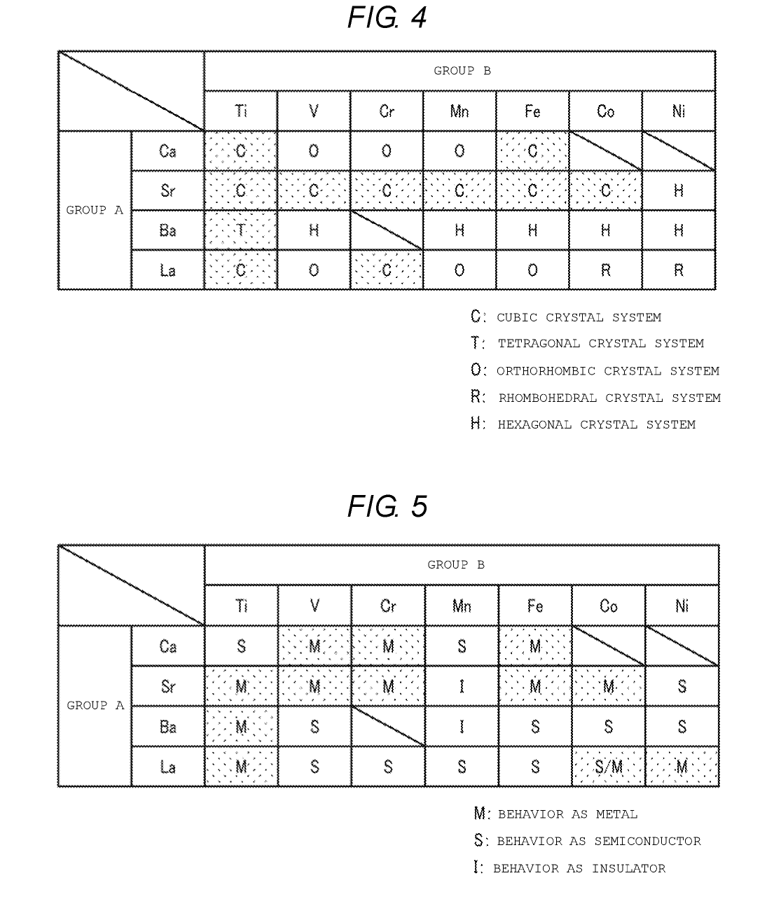

FIG. 4 is a table for describing a difference in crystal structure due to a combination of elements constituting the ferro-electric layer of the semiconductor memory device according to the first embodiment.

As illustrated in FIG. 4, when the ferro-electric layer 122 has the perovskite structure represented by ABO₃, the ferro-electric layer 122 can have various different crystal structures.

The ferro-electric layer 122 can have a crystal structure of a cubic crystal system when the combination of metal elements A and B is as follows: calcium (Ca) and titanium (Ti); calcium (Ca) andiron (Fe); strontium (Sr) and titanium (Ti); strontium (Sr) and vanadium (V); strontium (Sr) and chromium (Cr); strontium (Sr) and manganese (Mn); strontium (Sr) and iron (Fe); strontium (Sr) and cobalt (Co); lanthanum (La) and titanium (Ti); and lanthanum (La) and chromium (Cr). The ferro-electric layer 122 can have a crystal structure of a tetragonal crystal system when the combination of metal elements A and B is as follows: barium (Ba) and titanium (Ti). By the combination of zirconium (Zr) and hafnium (Hf), which are transition metal elements of the same series as titanium (Ti), with barium (Ba), a crystal structure of a tetragonal crystal system can be obtained. In FIG. 4, the combinations of the metal elements A and B, which can obtain the crystal structure of the cubic crystal system or the tetragonal crystal system, are illustrated by shading among the combinations of the metal elements A and B shown.

In addition, the ferro-electric layer 122 can have a crystal structure of an orthorhombic crystal system when the combination of the metal elements A and B is as follows: calcium (Ca) and vanadium (V); calcium (Ca) and chromium (Cr); calcium (Ca) and manganese (Mn); lanthanum (La) and vanadium (V); lanthanum (La) and manganese (Mn); and lanthanum (La) and iron (Fe). The ferro-electric layer 122 can have a crystal structure of a rhombohedral crystal system when the combination of the metal elements A and B is as follows: lanthanum (La) and cobalt (Co); and lanthanum (La) and nickel (Ni). The ferro-electric layer 122 can have a crystal structure of a hexagonal crystal system when the combination of the metal elements A and B is as follows: strontium (Sr) and nickel (Ni); barium (Ba) and vanadium (V); barium (Ba) and manganese (Mn); barium (Ba) and iron (Fe); barium (Ba) and cobalt (Co); and barium (Ba) and nickel (Ni).

Generally, in the case of growing a crystal structure of one of two layers adjacent to each other using a crystal structure of the other layer as a nucleus, the more the two layers have a similar inherent crystal structure, the more a highly-oriented crystal grows. As the highly-oriented crystal grows, a high tunnel magneto-resistance effect and a high tunnel electro-resistance effect can be obtained, which leads to improvement, i.e., reduction, of the resistance ratio of the variable resistance element 22. Therefore, the ferro-electric layer 122 desirably has a crystal structure similar to that of the para-electric layer 121 so as to obtain the highly-oriented crystal structure. Specifically, the ferro-electric layer 122 desirably has a crystal structure of a cubic crystal system or a tetragonal crystal system with respect to the para-electric layer 121 having the crystal structure of the cubic crystal system. Therefore, when the ferro-electric layer 122 has a perovskite structure represented by ABO₃, the combination (illustrated by hatching in FIG. 4) of the metal elements A and B, which obtains the cubic crystal system or the tetragonal crystal system, is desirably selected from the combinations described above.

1.1.4.2 Lattice Constant

A lattice constant of the ferro-electric layer 122 will be described below.

In general, when a crystal structure of one of two layers adjacent to each other grows using a crystal structure of the other layer as a nucleus, a highly-oriented crystal easily grows if the crystal structures of the two layers have lattice constants of similar values, and the highly-oriented crystal easily grows. Therefore, the ferro-electric layer 122 desirably has a crystal structure having a lattice constant similar to that of the para-electric layer 121.

For example, when the para-electric layer 121 is formed of magnesium oxide (MgO), the para-electric layer 121 has a lattice constant of about 4.2 Å (1 Å=1.0×10⁻¹⁰ m). In this case, the ferro-electric layer 122 desirably has a lattice constant within a range of several % (for example, no more than about 5%) from 4.2 Å.

For example, in the case of the combination of barium (Ba) and titanium (Ti) in the combinations of the metal elements A and B indicated in FIG. 4, the lattice constant is 4.0 Å. Therefore, when the ferro-electric layer 122 contains barium titanium oxide (BaTiO₃) having a perovskite structure, a highly-oriented crystal structure can be obtained.

In addition, zirconium (Zr) and hafnium (Hf), which are transition metal elements of the same series as titanium (Ti), have a larger ion radius than titanium (Ti). Therefore, the combination of barium (Ba) and zirconium (Zr) and barium (Ba) and hafnium (Hf) has a lattice constant of about 4.2 Å. Accordingly, when the ferro-electric layer 122 contains barium zirconium oxide (BaZrO₃) or barium hafnium oxide (BaHfO₃) having a perovskite structure, it is possible to obtain a more highly-oriented crystal structure.

When the ferro-electric layer 122 has different lattice constants of two layers adjacent to each other with ferro-electric layer interposed therebetween, a bonding distance at both interfaces is displaced by the asymmetry of the lattice constant, and a large tunnel electro-resistance effect can be obtained. Here, when the ferromagnetic layer 130 contains cobalt-iron-boron (FeCoB), a lattice distance of the ferromagnetic layer 130, which is lattice-matched with the ferro-electric layer 122, is around 4.0 Å when the ferro-electric layer 122 is oriented with an angle of 45 degrees with respect to the ferromagnetic layer 130, and satisfies the above-described condition. In this case, the ferro-electric layer 122 can have a highly-oriented crystal structure due to the consistency of the lattice constant with the para-electric layer 121, and a tunnel electro-resistance effect thereof can be improved due to asymmetry between the lattice constant of the para-electric layer 121 and the lattice constant of the ferromagnetic layer 130. In this way, the ferro-electric layer 122 contains barium titanium oxide (BaTiO₃) and also has a perovskite structure obtained by substituting titanium (Ti) with zirconium (Zr) or hafnium (Hf), whereby the lattice constant thereof is desirably set to 4.0 to 4.2 Å.

In addition, the lattice constant of the ferro-electric layer 122 is desirably set to a value between lattice constants of the ferromagnetic layer 130 and the para-electric layer 121.

Such a setting is based on the fact that, when the ferro-electric layer 122 has different lattice constants of two layers adjacent to each other with ferro-electric layer interposed therebetween, a bonding distance at both interfaces is displaced by the asymmetry of the lattice constant and a large tunnel electro-resistance effect is obtained, and the fact that, when a crystal structure of one of two layers adjacent to each other grows using a crystal structure of the other layer as a nucleus, a highly-oriented crystal easily grows if the crystal structures of the two layers have lattice constants of similar values, and the highly-oriented crystal easily grows. Although the resistance ratio increases as the lattice constant is different, too much difference in lattice constant slows down crystal growth and the resistance ratio decreases.

1.1.4.3 Bonding Force to Oxygen

A binding strength between the ferro-electric layer 122 and oxygen will be described below.

The ferro-electric layer 122 having the perovskite structure contains an oxygen element (O). In a case where the binding strength between the metal elements A and B contained in the ferro-electric layer 122 and the oxygen element (O) is weak, the oxygen element (O) contained in the ferro-electric layer 122 diffuses to the adjacent electrode in the crystallization process, and thus oxidation of the electrode may occur. The oxidation of the electrode leads to deterioration in performance of the variable resistance element 22. For this reason, the combination of the metal elements A and B used for the ferro-electric layer 122 desirably has characteristics of a strong binding strength to the oxygen element (O).

In the combination of the metal elements A and B illustrated in FIG. 4, the combination of barium (Ba) and titanium (Ti) has a strong bonding force to the oxygen element (O). Therefore, when the ferro-electric layer 122 contains barium titanium oxide (BaTiO₃) having the perovskite structure, it is possible to prevent the diffusion of the oxygen element (O) into other layers of the variable resistance element 22 during the crystallization process.

In addition, the combination of barium (Ba) and zirconium (Zr) and the combination of barium (Ba) and hafnium (Hf) also have a strong binding strength to the oxygen element (O). Accordingly, even when the ferro-electric layer 122 contains barium zirconium oxide (BaZrO₃) or barium hafnium oxide (BaHfO₃) having the perovskite structure, it is possible to prevent the diffusion of the oxygen element (O) into other layers of the variable resistance element 22 during the crystallization process.

1.1.4.4 Parasitic Resistance

The parasitic resistance of the ferro-electric layer 122 will be described below.

FIG. 5 is a table for describing a difference in parasitic resistance due to the combination of elements constituting the ferro-electric layer of the semiconductor memory device according to the first embodiment.

As illustrated in FIG. 5, In the case of where the ferro-electric layer 122 has the perovskite structure represented by ABO₃, the magnitude of the parasitic resistance of the ferro-electric layer 122 can vary depending on the constituent elements thereof. Specifically, the ferro-electric layer 122 acts as a metal when the combination of the metal elements A and B is as follows: calcium (Ca) and vanadium (V); calcium (Ca) and chromium (Cr); calcium (Ca) and iron (Fe); strontium (Sr) and titanium (Ti); strontium (Sr) and vanadium (V); strontium (Sr) and chromium (Cr); strontium (Sr) and iron (Fe); strontium (Sr) and cobalt (Co); barium (Ba) and titanium (Ti); lanthanum (La) and titanium (Ti); lanthanum (La) and cobalt (Co); and lanthanum (La) and nickel (Ni). By the combination of zirconium (Zr) and hafnium (Hf), which are transition metal elements of the same series as titanium (Ti), with barium (Ba), the ferro-electric layer 122 acts as a metal. In FIG. 5, the combinations of the metal elements A and B, which acts as a metal, are illustrated by hatching among the combinations of the metal elements A and B.

In addition, the ferro-electric layer 122 acts as a semiconductor when the combination of the metal elements A and B is as follows: calcium (Ca) and titanium (Ti); calcium (Ca) and manganese (Mn); strontium (Sr) and nickel (Ni); barium (Ba) and vanadium (V); barium (Ba) and iron (Fe); barium (Ba) and cobalt (Co); barium (Ba) and nickel (Ni); lanthanum (La) and vanadium (V); lanthanum (La) and chromium (Cr); lanthanum (La) and manganese (Mn); lanthanum (La) andiron (Fe); and lanthanum (La) and cobalt (Co). A ferro-electric layer 122 acting as a semiconductor may have a larger parasitic resistance than a ferro-electric layer 122 acting as a metal.

In addition, the ferro-electric layer 122 acts as an insulator when the combination of the metal elements A and B is as follows: strontium (Sr) and manganese (Mn); and barium (Ba) and manganese (Mn). A ferro-electric layer 122 acting as an insulator may have a larger parasitic resistance than a ferro-electric layer 122 acting as a metal or a as semiconductor.

In order to increase the ratio of the read current flowing in the variable resistance element 22 in each of the low resistance state and the high resistance state, the parasitic resistance in the variable resistance element 22 becomes desirably smaller. Therefore, when the ferro-electric layer 122 has the perovskite structure represented by ABO₃, the combination (illustrated by hatching in FIG. 5) of the metal elements A and B, which acts as a metal, is desirably selected from the combinations described above.

1.1.4.5 Candidate Configuration of Ferro-Electric Layer

When the ferro-electric layer 122 has the perovskite structure represented by ABO₃, as a candidate configuration for satisfying the above-described conditions, the ferro-electric layer 122 desirably contains any one of barium titanium oxide (BaTiO₃), barium zirconium oxide (BaZrO₃), and barium hafnium oxide (BaHfO₃). In addition, the ferro-electric layer 122 may be formed of Ba(Ti, Zr, Hf)O₃, Ba(Ti, Zr)O₃, Ba(Ti, Hf)O₃, or Ba(Zr, Hf)O₃ which is a material obtained by adjusting a composition ratio of titanium (Ti), zirconium (Zr), and hafnium (Hf).

In this case, the ferro-electric layer 122 can grow a highly-oriented crystal structure in a relatively easy manner and can prevent the oxidation of the adjacent layers, so that it is also advantageous from the viewpoint of ease of manufacture. Further, since the parasitic resistance of the ferro-electric layer 122 can be reduced, it is also advantageous from the viewpoint of reducing the write current.

### 1.2 Write Operation

A write operation of the semiconductor memory device according to the first embodiment will be described below. The following description will be given with respect to changes in the states of the reference layer RL, the para-electric layer PEL, the ferro-electric layer FEL, and the storage layer SL among the components in the variable resistance element 22.

1.2.1 Overview of Write Operation

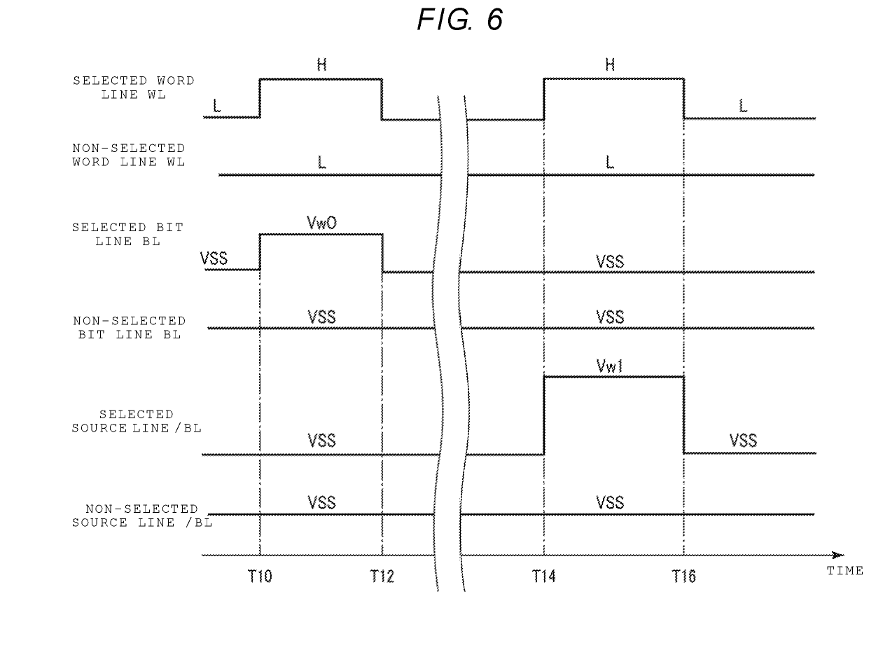

First, an overview of the write operation in the semiconductor memory device according to the first embodiment will be described with reference to FIG. 6. FIG. 6 is a timing chart for describing the overview of the write operation in the semiconductor memory device according to the first embodiment. FIG. 6 illustrates a state in which a voltage for writing data of “0” is supplied to the memory cell MC to be written during a period from a time T10 to a time T12. In addition, FIG. 6 illustrates a state in which a voltage for writing data of “1” is supplied during from time a T14 to time a T16.

In the following description, the memory cell MC to be written is referred to as a “selected memory cell MC”, and bit line BL and word line WL corresponding to the selected memory cell MC are referred to as “selected bit line BL and selected word line WL”. Further, bit line BL and word line WL not corresponding to the selected memory cell MC are referred to as “non-selected bit line BL and non-selected word line WL”.

First, an operation of writing data of “0” will be described.

As illustrated in FIG. 6, for example, a voltage VSS is supplied to the bit line BL until the time T10. For example, an “L”-level voltage for turning off the select transistor 21 is supplied to the word line WL.

At the time T10, voltages Vw0 and VSS are supplied to the selected bit line BL and the selected source line /BL, respectively. In addition, an “H”-level voltage for turning on the select transistor 21 is supplied to the selected word line WL. Thus, a current flows from the selected bit line BL toward the selected source line /BL in the variable resistance element 22 within the selected memory cell MC.

Meanwhile, a voltage VSS is supplied to the non-selected bit line BL and the non-selected source line /BL, and an “L”-level voltage is supplied to the non-selected word line WL. Thus, no current flows in the variable resistance element 22 within the non-selected memory cell MC.

At the time 112, a voltage VSS is supplied to the selected bit line BL. In addition, an “L”-level voltage is supplied to the selected word line WL. Thus, the supply of the current to the selected memory cell MC is stopped.

Thus, the operation of writing the data of “0” to the selected memory cell MC is completed.

An operation of writing data of “1” will be described below with reference to FIG. 6.

For example, a voltage VSS is supplied to the bit line BL and the source line /BL until the time T14. For example, an “L”-level voltage is supplied to the word line WL.

At the time T14, voltages VSS and Vw1 are supplied to the selected bit line BL and the selected source line /BL, respectively. For example, the voltage Vw1 is larger than the voltage Vw0. Further, an “H”-level voltage is supplied to the selected word line WL. Thus, a current flows from the selected source line /BL toward the selected bit line BL in the variable resistance element 22 within the selected memory cell MC.

Meanwhile, a voltage VSS is supplied to the non-selected bit line BL and the non-selected source line /BL, and an “L”-level voltage is supplied to the non-selected word line WL. Thus, no current flows in the variable resistance element 22 within the non-selected memory cell MC.

At the time T16, a voltage VSS is supplied to the selected source line /BL. Further, an “L”-level voltage is supplied to the selected word line WL. Thus, the supply of the current to the selected memory cell MC is stopped.

Thus, the operation of writing the data of “1” to the selected memory cell MC is completed.

1.2.2 Resistance Ratio in Write Operation

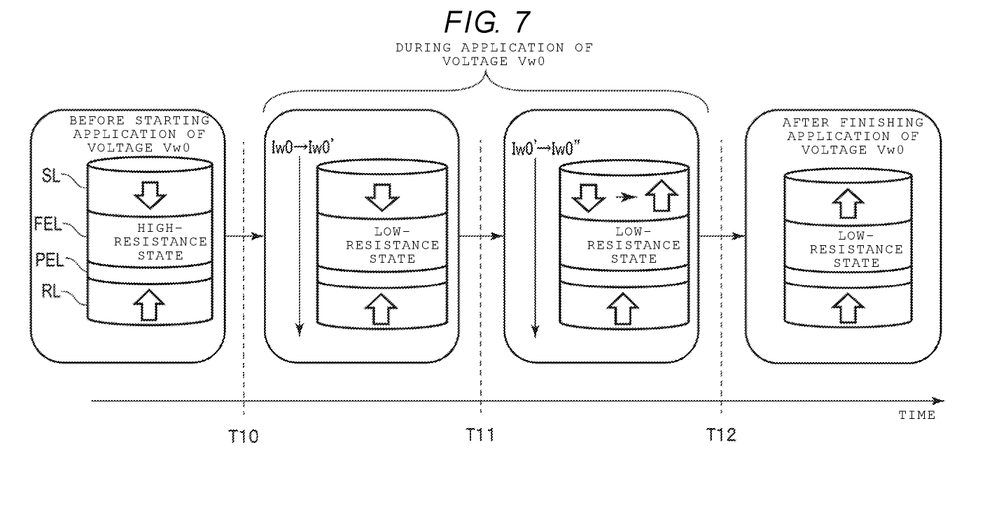

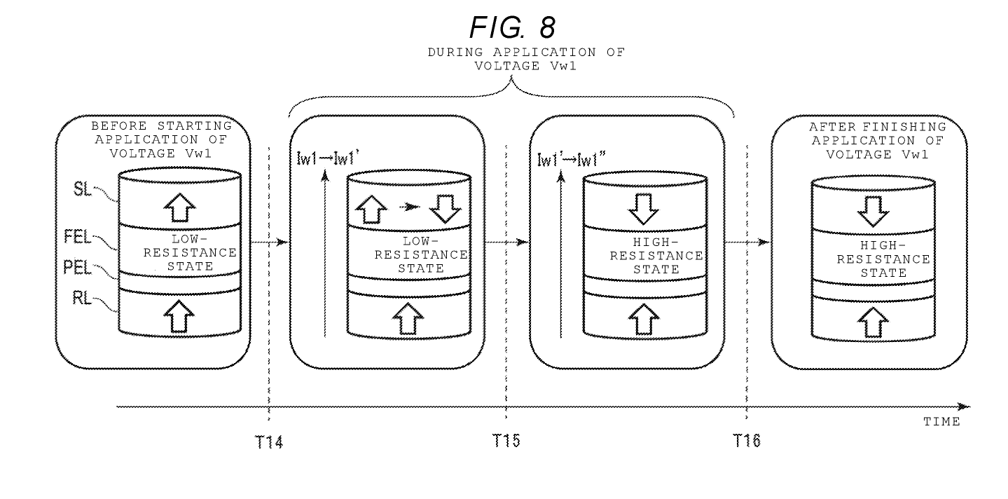

A resistance variation in the write operation of the semiconductor memory device according to the first embodiment will be described below with reference to FIGS. 7 and 8. FIG. 7 is a schematic diagram illustrating an example of resistance variation of the variable resistance element in the write operation of data of “0” in the semiconductor memory device according to the first embodiment. FIG. 7 illustrates a case where data of “0” is written from a state where data of “1” is written. FIG. 8 is a schematic diagram illustrating an example of resistance variation of the variable resistance element in the write operation of data of “1” in the semiconductor memory device according to the first embodiment. FIG. 8 illustrates a case where data of “1” is written from a state where data of “0” is written. The times T10 to T12 in FIG. 7 and the times T14 to T16 in FIG. 8 correspond to the times T10 to T16 in FIG. 6.

As illustrated in FIG. 7, until the time T10, the magnetization orientation of the storage layer SL is anti-parallel to the magnetization orientation of the reference layer RL. In addition, the ferro-electric layer FEL is in a high resistance state. In the operation of writing the data of “0”, since the controller 17 does not select the memory cell MC, no current flows in the variable resistance element 22.

During a period from the time T10 to the time T12, the controller 17 applies a voltage Vw0 to the variable resistance element 22 in the selected memory cell MC, and causes a current to flow from the storage layer SL toward the reference layer RL. More specifically, a current Iw0 flows in the variable resistance element 22 at the time T10.

During a period from the time T10 to the time T11, a voltage corresponding to the voltage Vw0 is applied to both ends of the ferro-electric layer FEL. Thus, the ferro-electric layer FEL transitions from the high resistance state to the low resistance state. Accordingly, the current Iw0 becomes a current Iw0′ larger than the current Iw0.

Subsequently, during a period from the time T11 to the time T12, a spin torque having a magnetization orientation parallel to the magnetization orientation of the reference layer RL is injected into the storage layer SL by the current Iw0′. Thus, the magnetization orientation of the storage layer SL is reversed to be parallel to the magnetization orientation of the reference layer RL. Accordingly, the current Iw0′ becomes a current Iw0″ larger than the current Iw0′.

At the time T12, the controller 17 stops applying the voltage Vw0 to the variable resistance element 22 in the selected memory cell MC. Even after the application of the voltage Vw0 is stopped, the variable resistance element 22 keeps the ferro-electric layer FEL in the low resistance state, and the magnetization orientation of the storage layer SL and the magnetization orientation of the reference layer RL are parallel to each other. Thus, the data of “0” is written.

Next, a change in magnetization orientation when the data of “1” is written from a state where the data of “0” is written.

As illustrated in FIG. 8, until the time T14, the magnetization orientation of the storage layer SL is parallel to the magnetization orientation of the reference layer RL. In addition, the ferro-electric layer FEL is in a low resistance state. In the operation of writing the data of “1”, since the controller 17 does not select the memory cell MC, no current flows in the variable resistance element 22.

During a period from the time T14 to the time T16, the controller 17 applies a voltage Vw1 to the variable resistance element 22 in the selected memory cell MC, and causes a current to flow from the reference layer RL toward the storage layer SL. More specifically, a current Iw1 flows in the variable resistance element 22 at the time T14.

During a period from the time T14 to the time T15, a spin torque having a magnetization orientation anti-parallel to the magnetization orientation of the reference layer RL is injected into the storage layer SL by the current Iw1. Thus, the magnetization orientation of the storage layer SL is reversed to be anti-parallel to the magnetization orientation of the reference layer RL. Accordingly, the current Iw1 becomes a current Iw1′ smaller than the current Iw1.

Subsequently, during a period from the time T15 to the time T16, the magnetization orientation of the storage layer SL is reversed to be anti-parallel, so that the voltage applied to the variable resistance element 22 rises and the ferro-electric layer FEL transitions from the low resistance state to the high resistance state. Accordingly, the current Iw1′ becomes a current Iw1″ smaller than the current Iw1′.

At the time T16, the controller 17 stops applying the voltage Vw1 to the variable resistance element 22 in the selected memory cell MC. Even after the application of the voltage Vw1 is stopped, the variable resistance element 22 keeps the ferro-electric layer FEL in the high resistance state, and the magnetization orientation of the storage layer SL and the magnetization orientation of the reference layer RL are anti-parallel to each other. Thus, the data of “1” is written.

Thus, the operation of writing the data to the selected memory cell MC is completed.

### 1.3 Method of manufacturing Variable Resistance Element

A method of manufacturing the variable resistance element of the semiconductor memory device according to the first embodiment will be described below. It is assumed that a forming process of the variable resistance element 22 roughly includes three types of forming processes P1, P2, and P3. In the forming processes P1 to P3, there is a trade-off relation between the magnitude of the resistance ratio of the variable resistance element 22 and the magnitude of the variation occurring between elements.

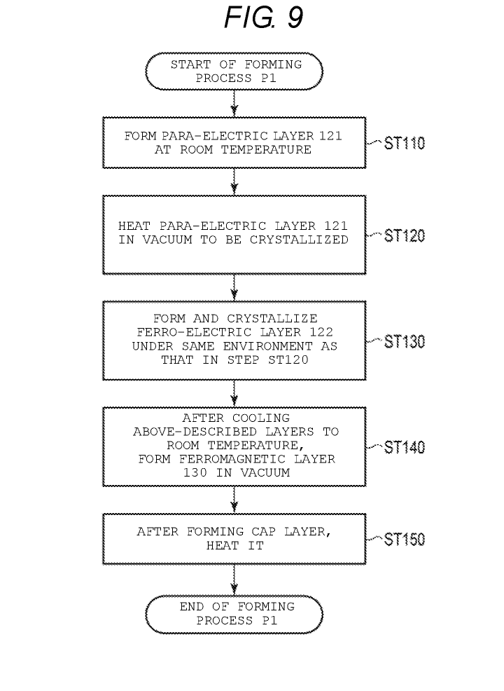

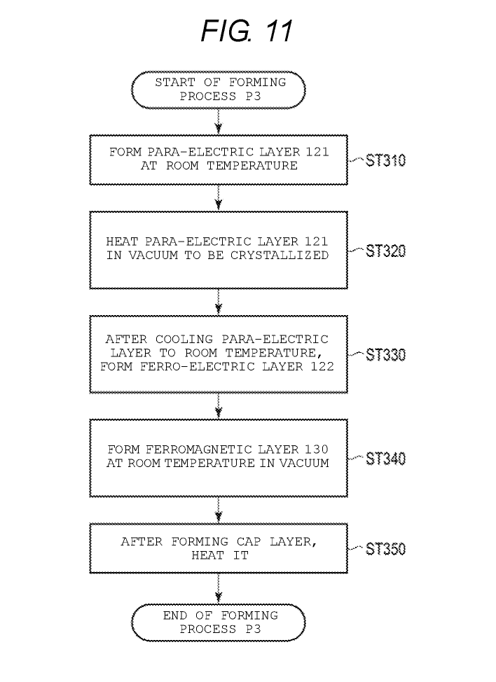

FIGS. 9, 10, and 11 are flowcharts for describing the method of manufacturing the variable resistance element of the semiconductor memory device according to the first embodiment. FIGS. 9 to 11 correspond to the forming processes P1 to P3, respectively. In the following description, the forming processes P1 to P3 of the layers 110 to 130 illustrated in FIG. 3 will be described with reference to FIGS. 9 to 11, respectively.

In the following description, it is assumed that iron-cobalt-boron (FeCoB) is applied to the ferromagnetic layers 110 and 130 and magnesium oxide (MgO) is applied to the para-electric layer 121.

1.3.1 Forming Process P1

First, the forming process P1 will be described.

As illustrated in FIG. 9, the para-electric layer 121 is formed on the ferromagnetic layer 110 at room temperature, for example around 20 C, in step ST110. Here, the para-electric layer 121 is in an amorphous state. The para-electric layer 121 is desirably formed to have a thickness of about 0.4 nm, for example.

In step ST120, the ferromagnetic layer 110 and the para-electric layer 121 are heated to 200 to 400° C. in a vacuum. At this high-temperature environment, the para-electric layer 121 is crystallized into a crystal structure of a tetragonal crystal system. The ferromagnetic layer 110 may be crystallized from the amorphous state at the same time in step ST120.

In step ST130, the ferro-electric layer 122 is formed on the para-electric layer 121 under the same environmental conditional as that in step ST120 (that is, in a state of being heated in a vacuum). Thus, the ferro-electric layer 122 is crystallized concurrently with the film formation thereof. During the crystallization, the ferro-electric layer 122 is crystallized from the location of the interface with the para-electric layer 121, using the crystal structure of the para-electric layer 121 as a nucleus.

In step ST140, the ferromagnetic layer 110, the para-electric layer 121, and the ferro-electric layer 122 are cooled to room temperature. After the cooling to room temperature is completed, the ferromagnetic layer 130 is formed on the ferro-electric layer 122 in a vacuum. Here, the ferromagnetic layer 130 is in an amorphous state.

In step ST150, after the cap layer is formed on the ferromagnetic layer 130, the structure including the cap layer and ferromagnetic layer 130 is heated at 300 to 500° C. as a whole. Thus, the ferromagnetic layer 130 is crystallized from the amorphous state.

Thus, the forming process P1 of the variable resistance element 22 is completed.

In the forming process P1, during the formation of the ferro-electric layer 122, the para-electric layer 121 is not temporarily cooled to the room temperature, and the ferro-electric layer 122 is formed and crystallized under the same high-temperature environment as that in which the para-electric layer 121 is crystallized. Thus, according to the forming process P1, the crystallization easily proceeds and a more ideal crystal structure is easily achieved. Therefore, the resistance ratio of the variable resistance element 22 can be maximized in the forming process P1 of the forming processes P1 to P3.

1.3.2 Forming Process P2

A forming process P2 will be described below. The forming process P2 differs from the forming process P1 in terms of forming conditions of the ferro-electric layer 122. Hereinafter, differences from the forming process P1 will be mainly described.

In steps ST210 and ST220, after being formed on the ferromagnetic layer 110, the para-electric layer 121 is crystallized. Steps ST210 and ST220 are the same as steps ST110 and ST120 described in FIG. 9, and thus the description thereof will not be presented.

In step ST230, the ferromagnetic layer 110 and the para-electric layer 121 are cooled to a room temperature. After the cooling to the room temperature is completed, the ferro-electric layer 122 is formed on the para-electric layer 121. Here, the ferro-electric layer 122 is in an amorphous state, and is adjusted to have a thickness of about 0.4 to 2.0 nm according to the resistance value.

In step ST240, the ferromagnetic layer 110, the para-electric layer 121, and the ferro-electric layer 122 are heated to 300 to 500° C. in a vacuum. Under the high-temperature environment, the ferro-electric layer 122 is crystallized.

In steps ST250 and ST260, after the ferromagnetic layer 130 and the cap layer are formed, the ferromagnetic layer 130 is crystallized. Steps ST250 and ST260 are the same as steps ST140 and ST150 described in FIG. 9, and thus the description thereof will not be presented.

Thus, the forming process P2 of the variable resistance element 22 is completed.

According to the forming process P2, since the ferro-electric layer 122 is formed under the room temperature environment, the flatness of the film surface can be kept higher than that in the forming process P1. For this reason, it is possible to reduce variations in characteristics of each element of the variable resistance element 22 in the forming process P2 as compared with the forming process P1.

1.3.3 Forming Process P3

A forming process P3 will be described below. The forming process P3 differs from the forming process P2 in that the ferro-electric layer 122 is crystallized after the ferromagnetic layer 130 is formed. Hereinafter, differences from the forming process P2 will mainly be described.

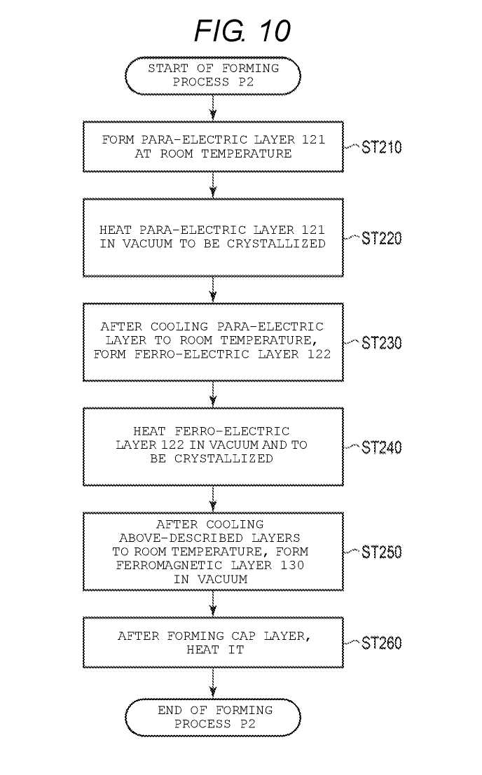

In steps ST310 and ST320, after being formed on the ferromagnetic layer 110, the para-electric layer 121 is crystallized. In step ST330, the ferro-electric layer 122 is formed on the para-electric layer 121. Steps ST310 to ST330 are the same as steps ST210 to ST230 described in FIG. 10, and thus the description thereof will not be presented.

In step ST340, the ferromagnetic layer 130 is formed on the ferro-electric layer 122 under a room temperature environment in a vacuum. Here, the ferromagnetic layer 130 is in an amorphous state.

In step ST350, after being formed on the ferromagnetic layer 130 in a vacuum, the structure including the ferromagnetic layers and the cap layer is heated at 300 to 500° C. as a whole. Thus, the ferro-electric layer 122 and the ferromagnetic layer 130 are crystallized from the amorphous state.

Thus, the forming process P3 of the variable resistance element 22 is completed.

According to the forming process P3, since ferromagnetic layer 130 is formed before the ferro-electric layer 122 is heated and crystallized, the flatness of the film surface can be kept higher than that in the forming process P2. For this reason, it is possible to minimize distribution in characteristics of each element of the variable resistance element 22 in the forming process P3 of the forming processes P1 to P3.

### 1.4 Effects according to Embodiment

According to the first embodiment, the resistance ratio (for example, magneto-resistive ratio and electro-resistive ratio) of the variable resistance element can be improved. Such an effect will be described below.

In the first embodiment, the ferro-electric layer 122 has the perovskite structure, and is in contact with the ferromagnetic layer 130. Thus, the ferro-electric layer 122 also functions as a tunnel barrier layer provided between the ferromagnetic layer 110 and the ferromagnetic layer 130. For this reason, the variable resistance element 22 including the ferro-electric layer 122 can function as a magnetic tunnel junction element that generates the tunnel magneto-resistance effect. In addition, the ferro-electric layer 122 can also function as a ferroelectric tunnel junction element that generates the tunnel electro-resistance effect. Therefore, the variable resistance element 22 generates the tunnel electro-resistance effect and the tunnel magneto-resistance effect at the same time, so that it is possible to obtain a higher resistance ratio as compared with the magneto-resistance effect element that generates only the tunnel magneto-resistance effect.

Further, the ferro-electric layer 122 is in contact with the para-electric layer 121 containing magnesium oxide (MgO). Thus, the crystal of the ferro-electric layer 122 grows using the crystal structure of the para-electric layer 121 as a nucleus in the crystallization process.

The ferro-electric layer 122 contains any one of barium titanium oxide (BaTiO₃), barium zirconium oxide (BaZrO₃), and barium hafnium oxide (BaHfO₃). Alternatively, the ferro-electric layer 122 may be formed of Ba(Ti, Zr, Hf)O₃, Ba(Ti, Zr)O₃, Ba(Ti, Hf)O₃, or Ba(Zr, Hf)O₃ that is a material obtained by adjusting a composition ratio of titanium (Ti), zirconium (Zr), and hafnium (Hf). Thus, the crystal structure of the ferro-electric layer 122 has a crystal structure similar to the crystal structure of the para-electric layer 121. In addition, the lattice constant of the ferro-electric layer 122 is equal to the lattice constant of the para-electric layer 121 within a range of several %. For this reason, the crystallization of the ferro-electric layer 122 can be promoted, and the ferro-electric layer 122 can have a highly-oriented crystal structure. Accordingly, it is possible to more easily manufacture the variable resistance element with improved resistance ratio.

In addition, barium titanium oxide (BaTiO₃), barium zirconium oxide (BaZrO₃), and barium hafnium oxide (BaHfO₃) are compounds having a relatively strong bonding force to oxygen with respect to other perovskite structures. For this reason, it is possible to prevent the diffusion of internal oxygen element (O) into other layers in the crystallization process, thereby preventing an increase in impurity concentration in the variable resistance element. Accordingly, it is possible to prevent a decrease in resistance ratio in the memory cell.

In addition, the barium titanium oxide (BaTiO₃), the barium zirconium oxide (BaZrO₃), and the barium hafnium oxide (BaHfO₃) act as a metal. For this reason, it is possible to reduce the parasitic resistance of the tunnel barrier layer as compared with other perovskite structures which act as a semiconductor or an insulator. Accordingly, an increase in the write voltage can be prevented.

In addition, as described above, the ferro-electric layer 122 is in contact with the ferromagnetic layer 130. Thus, the ferro-electric layer 122 can synergistically improve the tunnel magneto-resistance effect.

Additionally, the mechanism of the tunnel electro-resistance effect can mainly be described by three models (strain effect, electrostatic effect, and interface effect).

The first strain effect is an effect that a physical strain occurs in the ferro-electric layer due to the application of an electric field and the resistance value of the ferro-electric layer changes due to the strain. The second electrostatic effect is an effect that charges are accumulated at both interfaces of the ferro-electric layer due to the application of an electric field and the resistance value of the ferro-electric layer changes due to the accumulation of the charges. The third interface effect is an effect that the coordination of the oxygen element (O) contained in the ferro-electric layer changes due to the application of an electric field and the resistance value of the ferro-electric layer changes due to the change of the coordination.

Charges are accumulated at the interface between the ferro-electric layer 122 and the ferromagnetic layer 130 when a write current flows. Thus, it is possible to change the electrical charge state at the interface between the ferro-electric layer 122 and the ferromagnetic layer 130. Meanwhile, the interface magnetic anisotropy of the ferromagnetic layer 130 is changed depending on the differential electrical charge state of at the interface with the tunnel barrier layer 120. For this reason, the interface magnetic anisotropy of the ferromagnetic layer 130 can be largely changed when the write current flows as compared with the magneto-resistance effect element having a configuration in which the ferromagnetic layer 130 is not in contact with the ferro-electric layer 122 (for example, being in contact with the para-electric layer 121). Accordingly, the resistance ratio can be made larger.

Further, the ferromagnetic layer 130 functions as the storage layer SL. Therefore, the magnetization orientation of the ferromagnetic layer 130 can be easily reversed with the change of the interface magnetic anisotropy due to the electrostatic effect of the ferro-electric layer 122. Accordingly, the magnetization orientation of the ferromagnetic layer 130 may be reversed with a smaller write current.

### 2. Modifications

In the semiconductor device according to the first embodiment, the barium (Ba)-based perovskite structure is desirable for the ferro-electric layer 122, but various modifications are applicable.

### 2.1 First Modification

For example, the ferro-electric layer 122 may have a lanthanum (La)-based perovskite structure.

The lanthanum (La)-based perovskite structure has a smaller ion radius than the barium (Ba)-based perovskite structure. Thus, the lattice constant of the lanthanum (La) -based perovskite structure can be about 3.8 Å. Therefore, when the para-electric layer 121 contains magnesium oxide (MgO), the difference in the lattice constant becomes about 10%, and it is possible to obtain a highly-oriented crystal film which is substantially the same crystal structure as the barium (Ba)-based perovskite structure.

However, the lanthanum (La)-based perovskite structure can make the parasitic resistance smaller than the barium (Ba)-based perovskite structure. Therefore, when the orientation of the crystal film described above is acceptable, the lanthanum (La) -based perovs kite structure maybe effective as an embodiment of the disclosure.

Accordingly, the ferro-electric layer 122 may contain, for example, any one of lanthanum nickel oxide (LaNiO₃) and lanthanum aluminum oxide (BaAlO₃) which are have a perovskite structure.

In addition, the ferro-electric layer 122 may use materials in which barium (Ba) is partially substituted with lanthanum (La) for each of barium titanium oxide (BaTiO₃), barium zirconium oxide (BaZrO₃), barium hafnium oxide (BaHfO₃), and Ba(Ti, Zr, Hf)O₃, Ba(Ti, Zr)O₃, Ba(Ti, Hf)O₃, or Ba(Zr, Hf)O₃ which is a material obtained by adjusting a composition ratio of titanium (Ti), zirconium (Zr), and hafnium (Hf).

### 2.2 Second Modification

In ABO₃ having the barium (Ba) -based perovskite structure or the lanthanum (La) -based perovskite structure as described above, some of the elements corresponding to the element A are substituted with bismuth (Bi) and some of the elements corresponding to the element B are substituted with manganese (Mn), iron (Fe), or cobalt (Co), so that the ferro-electric layer 122 has magnetism and thus the resistance ratio thereof can be increased.

In this case, the magnetization direction of the storage layer SL and the magnetization direction of the reference layer RL changes from the parallel state to the anti-parallel state, whereby the angle formed by the magnetization directions of the storage layer SL, the reference layer RL, and the ferro-electric layer 122 is changed. This makes it possible for the ferro-electric layer 122 to exchange splitting to improve barrier height difference and resistance ratio.

### 3. Others

Although the case where the variable resistance element 22 described in the first embodiment and the modifications is a top free type in which the storage layer SL is provided above the reference layer RL, the variable resistance element 22 may be a bottom free type in which the storage layer SL is provided below the reference layer RL.

In the write operation described in the first embodiment, the operation of controlling the write voltage to write the data to the variable resistance element 22 is described, but the disclosure is not limited thereto. For example, the write operation may be performed by controlling the write current, or by combining of the control of the write voltage and the control of the write current. In the case of combining the control of the write voltage and the control of the write current, the write voltage and the write current may be separately used and controlled depending on the change in the resistance state due to the reversal of the magnetization orientation of the storage layer and the change in the resistance state of the ferro-electric layer.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein maybe made without departing from the spirit of the inventions. The accompanying claims and their equivalents are intended to cover such forms or modifications as would fall within the scope and spirit of the inventions.

What is claimed is:

1. A semiconductor memory device, comprising:
a variable resistance element comprising a first ferromagnetic layer, a second ferromagnetic layer, and a non-magnetic layer between the first ferromagnetic layer and the second ferromagnetic layer, wherein
the non-magnetic layer includes:
a para-electric layer on an upper surface of the first ferromagnetic layer, and
a ferro-electric layer on an upper surface of the para-electric layer and on a lower surface of the second ferromagnetic layer.

2. The device according to claim 1, wherein the ferro-electric layer has a perovskite structure.

3. The device according to claim 2, wherein the ferro-electric layer is made of ABO₃, where A includes at least one of barium (Ba) and lanthanum (La), B includes at least one of titanium (Ti), zirconium (Zr), and hafnium (Hf), and O is oxygen.

4. The device according to claim 2, wherein the ferro-electric layer is made of ABO₃, where A includes lanthanum (La), B includes at least one of aluminum (Al) and nickel (Ni), and O is oxygen.

5. The device according to claim 2, wherein the ferro-electric layer is made of a magnetic ABO₃, where A includes at least one of barium (Ba), bismuth (Bi), and lanthanum (La), B includes at least one of manganese (Mn), iron (Fe), and cobalt (Co), and O is oxygen.

6. The device according to claim 1, wherein the para-electric layer contains magnesium oxide.

7. The device according to claim 1, wherein the first ferromagnetic layer and the second ferromagnetic layer contain at least one of iron (Fe) and cobalt (Co).

8. The device according to claim 1, wherein the first ferromagnetic layer is a reference layer, the non-magnetic layer is a tunnel barrier layer, and the second ferromagnetic layer is a storage layer.

9. A semiconductor memory device, comprising:
a selection circuit;
a variable resistance element comprising a first ferromagnetic layer connected to the selection circuit, a second ferromagnetic layer, and a non-magnetic layer between the first ferromagnetic layer and the second ferromagnetic layer, wherein
the non-magnetic layer includes:
a para-electric layer on an upper surface of the first ferromagnetic layer; and
a ferro-electric layer on an upper surface of the para-electric layer and on a lower surface of the second ferromagnetic layer.

10. The memory device according to claim 9, wherein
the selection circuit comprises a transistor having a source, a drain, and a gate, and
the first ferromagnetic layer is electrically connected to one of the source and the drain.

11. The device according to claim 9, wherein the ferro-electric layer has a perovskite structure.

12. The device according to claim 11, wherein the ferro-electric layer is made of ABO₃, where A is at least one of barium (Ba) and lanthanum (La), B is at least one of titanium (Ti), zirconium (Zr), and hafnium (Hf), and O is oxygen.

13. The device according to claim 11, wherein the ferro-electric layer is made of ABO₃, where A is lanthanum (La), B is at least one of aluminum (Al) and nickel (Ni), and O is oxygen.

14. The device according to claim 11, wherein the ferro-electric layer is made of a magnetic ABO₃, where A is at least one of barium (Ba), bismuth (Bi), and lanthanum (La), B is at least one of manganese (Mn), iron (Fe), and cobalt (Co), and O is oxygen.

15. The device according to claim 9, wherein the para-electric layer contains magnesium oxide.

16. The device according to claim 9, wherein the first ferromagnetic layer and the second ferromagnetic layer contain at least one of iron (Fe) and cobalt (Co).

17. The device according to claim 9, wherein
the first ferromagnetic layer is a reference layer,
the non-magnetic layer is a tunnel barrier layer, and
the second ferromagnetic layer is a storage layer.

18. A memory device, comprising:
a reference layer comprising a first ferromagnetic material;
a storage layer comprising a second ferromagnetic material; and
tunnel barrier layer between the reference layer and the storage layer and comprising a perovskite layer contacting the storage layer.

19. The memory device according to claim 18, further comprising a crystalline layer interposed between the perovskite layer and the reference layer, and the lattice constants of the crystalline layer and the perovskite layer differ by no more than about 5%.

20. The memory device according to claim 18, wherein the perovskite layer is made of ABO₃, where:
A is at least one of barium (Ba) and lanthanum (La), B is at least one of titanium (Ti), zirconium (Zr), and hafnium (Hf), and O is oxygen; or
A is lanthanum (La), B is at least one of aluminum (Al) and nickel (Ni), and O is oxygen; or
A is at least one of barium (Ba), bismuth (Bi), and lanthanum (La), B is at least one of manganese (Mn), iron (Fe), and cobalt (Co), and O is oxygen.
